(19) United States
(12) Patent Application Publication
(10) Pub. No.: US 2026/0076028 A1
(43) Pub. Date: Mar. 12, 2026

(54) ORGANIC LIGHT EMITTING DIODE UTILIZING SPIN-POLARIZED CHARGE CARRIER INJECTION

(71) Applicant: IUCF-HYU (INDUSTRY-UNIVERSITY COOPERATION FOUNDATION HANYANG UNIVERSITY), Seoul (KR)

(72) Inventors: Young-Hoon KIM, Seoul (KR); Su Hwan LEE, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/287,636

(22) Filed: Jul. 31, 2025

(30) Foreign Application Priority Data
Jul. 31, 2024 (KR) 10-2024-0102010
Jul. 31, 2025 (KR) 10- 2025-0104783

(51) Int. Cl. H10K 50/15; H10K 50/12; H10K 50/16; H10K 50/17; H10K 50/82; H10K 101/00; H10K 101/40; H10K 101/70

(52) U.S. Cl. CPC H10K 50/15; H10K 50/12; H10K 50/16; H10K 50/82; H10K 50/17; H10K 50/171; H10K 2101/40; H10K 2101/70; H10K 2101/90

(57) ABSTRACT

An organic light-emitting diode is provided. The organic light-emitting diode includes an anode, a cathode, and a light-emitting layer disposed therebetween. The cathode includes a ferromagnetic metal layer that selectively conducts spin-polarized electrons. An electron-conduction layer is disposed between the cathode and the light-emitting layer. A spin-polarizing hole-transport layer that supplies spin-polarized holes to the light-emitting layer is disposed between the anode and the light-emitting layer. The spin-polarized electrons and the spin-polarized holes recombine within the light-emitting layer.

### CLAIM FOR PRIORITY

This application claims priority to Korean Patent Applications No. 2024-0102010 filed on Jul. 31, 2024 and No. 2025-0104783 filed on Jul. 31, 2025 in the Korean Intellectual Property Office (KIPO), the entire contents of which are hereby incorporated by reference.

### BACKGROUND

### 1. Technical Field

The present invention relates to organic optoelectronic devices, specifically to organic light-emitting diodes.

### 2. Related Art

Organic light-emitting diodes (OLEDs), one type of organic optoelectronic device, are self-emitting devices. They offer advantages such as a wide viewing angle, excellent contrast, fast response time, superior luminance, superior driving voltage, and superior response speed characteristics, as well as the capability for multicolor display.

A typical organic light-emitting diode may include an anode, a cathode, and organic layers interposed between the anode and cathode. The organic layers may include a hole injection layer, a hole transport layer, a light-emitting layer, an electron transport layer, and an electron injection layer. When a voltage is applied between the anode and cathode, holes injected from the anode move through the hole transport layer to the light-emitting layer, and electrons injected from the cathode move through the electron transport layer to the light-emitting layer. These carriers, such as holes and electrons, combine in the light-emitting layer region to generate excitons. As these excitons transition to the ground state, light is emitted.

Typically, excitons generated during operation of the organic light-emitting diode are probabilistically produced in a singlet state (25%) and a triplet state (75%). In the case of fluorescent light-emitting materials, only the 25% of excitons in the singlet state generate luminescence, limiting the internal quantum efficiency to a maximum of approximately 25%. To improve this characteristic, iridium or platinum complexes capable of utilizing triplet energy are employed, known to possess excellent quantum efficiency properties. However, these materials are expensive, and their application is limited, particularly due to the instability of blue light-emitting materials.

### SUMMARY

Accordingly, example embodiments of the present invention provide an organic light-emitting diode with significantly enhanced internal quantum efficiency.

Example embodiments of the present invention provide an organic light-emitting diode. The organic light-emitting diode includes an anode, a cathode, and a light-emitting layer disposed between them. The cathode includes a ferromagnetic metal layer that selectively conducts spin-polarized electrons. An electron conduction layer is disposed between the cathode and the light-emitting layer. A spin-polarizing hole transport layer, which injects spin-polarized holes to the light-emitting layer, is disposed between the anode and the light-emitting layer. The spin-polarized electrons and the spin-polarized holes recombine within the light-emitting layer.

The spin-polarized electrons and the spin-polarized holes may have spin states in opposite directions. The ratio of singlet excitons among excitons generated by combination of the spin-polarized electrons and the spin-polarized holes within the light-emitting layer may be greater than 25% and less than or equal to 100%. The light-emitting layer maybe a fluorescent light-emitting layer.

The light-emitting layer may include a host and a dopant, and the spin-polarized electrons and the spin-polarized holes may be injected directly into the dopant without passing through the host and may recombine within the dopant. A HOMO (Highest Occupied Molecular Orbital) energy level of the host is lower than a HOMO energy level of the dopant, and a LUMO (Lowest Unoccupied Molecular Orbital) energy level of the host may be higher than a LUMO energy level of the dopant. A difference between a HOMO energy level of the hole transport layer and the HOMO energy level of the host may create an energy barrier for the spin-polarized holes, thereby blocking an injection of the spin-polarized holes into the host. A difference between a LUMO energy level of the electron conduction layer and the LUMO energy level of the host may create an energy barrier for the spin-polarized electrons, thereby blocking an injection of the spin-polarized electrons into the host.

The host may be a mixed host of an electron donor and an electron acceptor. A HOMO energy level of the electron donor and a HOMO energy level of the electron acceptor may be lower than the HOMO energy level of the dopant, and a LUMO energy level of the electron donor and a LUMO energy level of the electron acceptor may be higher than the LUMO energy level of the dopant. The difference between the HOMO energy level of the hole transport layer and the HOMO energy level of the electron donor may create an energy barrier for the spin-polarized holes, thereby blocking an injection of the spin-polarized holes into the electron donor. The difference between the LUMO energy level of the electron conduction layer and the LUMO energy level of the electron acceptor may create an energy barrier for the spin-polarized electrons, thereby blocking an injection of the spin-polarized electrons into the electron acceptor.

The spin-polarizing hole transport layer may be a layer having a chiral asymmetric structure exhibiting either R-chiral or S-chiral chirality. The spin-polarizing hole transport layer may be a chiral metal oxide layer, a chiral perovskite layer, or a chiral organic semiconductor layer.

The chiral perovskite layer may include a perovskite having a chemical formula of ABX₃, A′₂Aₙ₋₁BX₃ₙ₊₁, ABX₄, A₂BX₄, A₂BX₅, A₃BX₅, A₄B₂X₁₀, ABX₅, A₃B₂X₉, AB₂X₁₀ or A₂B₁B′X₆, wherein the A may be an R- or S-chiral organic cation, the A′ may be a chiral organic cation having a same chirality as the A but having a different composition, and the B and the B′ may be, independently of each other, metal ions, achiral organic cations, inorganic cations, achiral ammonium ions, or combinations thereof. The X may be F⁻, Cl⁻, Br⁻, I⁻, or combinations thereof and the n may be an integer from 1 to 10.

The chiral perovskite layer may be a two-dimensional layered perovskite layer. The chiral perovskite layer may be a perovskite layer having the chemical formula A₂BX₄.

The ferromagnetic metal layer may be Fe, Ni, Co, FeCo, NiFe, or a composite film thereof. The cathode may further include a cathode conductive film, which is a conductive film having a lower work function than the anode. The electron conduction layer may include an electron transport layer adjacent to the light-emitting layer and an electron injection layer adjacent to the cathode.

An organic light-emitting diode (OLED) according to an embodiment of the present invention can generate singlet excitons at a higher rate than triplet excitons within the emitting layer by injecting spin-aligned holes and spin-aligned electrons into the emitting layer, thereby generating only singlet excitons. As a result, a fluorescent OLED exhibiting an internal quantum efficiency exceeding 25%, and theoretically up to 100%, is possible. Since this OLED theoretically follows the existing fluorescence emission mechanism, it can exhibit a nanosecond emission lifetime and high stability, thereby overcoming the low emission stability that has been a challenge for existing phosphorescent/delayed fluorescent/super fluorescent blue emitters and blue light-emitting diodes.

In another example, an OLED can generate only triplet excitons within the emitting layer by injecting spin-aligned holes and spin-aligned electrons into the emitting layer.

### BRIEF DESCRIPTION OF DRAWINGS

Example embodiments of the present invention will become more apparent by describing in detail example embodiments of the present invention with reference to the accompanying drawings, in which:

FIG. 1 is a cross-sectional view showing an organic light-emitting diode according to an embodiment of the present invention.

FIG. 2 is a schematic diagram showing an energy band diagram of an organic light-emitting diode according to an embodiment of the present invention.

FIGS. 3a and 3b are schematic diagrams showing the emission mechanisms of a conventional fluorescent organic light-emitting diode and a fluorescent organic light-emitting diode according to an embodiment of the present invention, respectively.

FIG. 4 is a schematic diagram showing an energy band diagram of an organic light-emitting diode according to an embodiment of the present invention when a host in a light-emitting layer is a mixed host.

FIG. 5 schematically illustrates the phenomenon observed when no energy barrier forms between a HOMO of the electron donor and a HOMO of the hole transport layer, and when no energy barrier forms between a LUMO of the electron acceptor and a LUMO of the electron transport layer.

FIGS. 6a and 6b show graphs representing the spin-polarized currents of the structures according to Manufacturing Example 1A and Manufacturing Example 1B, respectively.

FIGS. 7a and 7b show graphs representing the spin-polarized currents of the structures according to Manufacturing Example 2A and Manufacturing Example 2B, respectively.

FIGS. 8a, 8b, and 8c show graphs representing the spin-polarized current of the structures according to Manufacturing Example 1A, Manufacturing Example 2A, and Manufacturing Example 3A, respectively.

FIGS. 9a and 9b are schematic diagrams illustrating, respectively, the structure of the spin-polarizing hole transport layer and the Chirality-Induced Spin Selectivity (CISS) exhibited therethrough.

FIGS. 10a, 10b, and 10c shows, respectively, a schematic diagram illustrating the layered structure of the organic light-emitting diode (OLED) according to Manufacturing Example 4, a graph showing Normalized External Quantum Efficiency of the OLEDs according to Manufacturing Example 4 and Comparative Example, and a graph showing Normalized Current Efficiency of the OLEDs according to Manufacturing Example 4 and Comparative Example.

### DESCRIPTION OF EXAMPLE EMBODIMENTS

Hereinafter, preferred embodiments of the present invention will be described in greater detail with reference to the accompanying drawings to more specifically explain the present invention. However, the present invention is not limited to the embodiments described herein and may be embodied in other forms. Throughout the specification, like reference numerals denote like elements.

When an element such as a layer, region, or substrate is referred to as being ‘on’ another element, it will be understood that it can be directly on the other element or intervening elements may be present therebetween.

In the present specification, up spin and down spin merely mean mutually opposite spins, and which spin is called up spin and which spin is called down spin may vary depending on the reference set by the observer.

In the present specification, the energy level means the magnitude of energy. Accordingly, even when the energy level is indicated in the minus (−) direction from the vacuum level (energy level 0), the energy level is interpreted as meaning the absolute value of the corresponding energy value. For example, a HOMO (Highest Occupied Molecular Orbital) energy level of a host means the distance from the vacuum level to the HOMO. Furthermore, a LUMO (Lowest Unoccupied Molecular Orbital) energy level of the host means the distance from the vacuum level to the LUMO.

Furthermore, a CBM (Conduction Band Minimum) of the host refers to the lowest edge of the conduction band of the material, and a VBM (valence band maximum) of the host refers to the highest edge of the valence band of the material. The difference between the CBM and the VBM is referred to as a bandgap.

In the present specification, the expression that the energy level is low means that the distance from the vacuum level to the energy level is large, and in other words, the energy level is deep. Conversely, the expression that the energy level is high means that the distance from the vacuum level to the energy level is small, and in other words, the energy level is shallow.

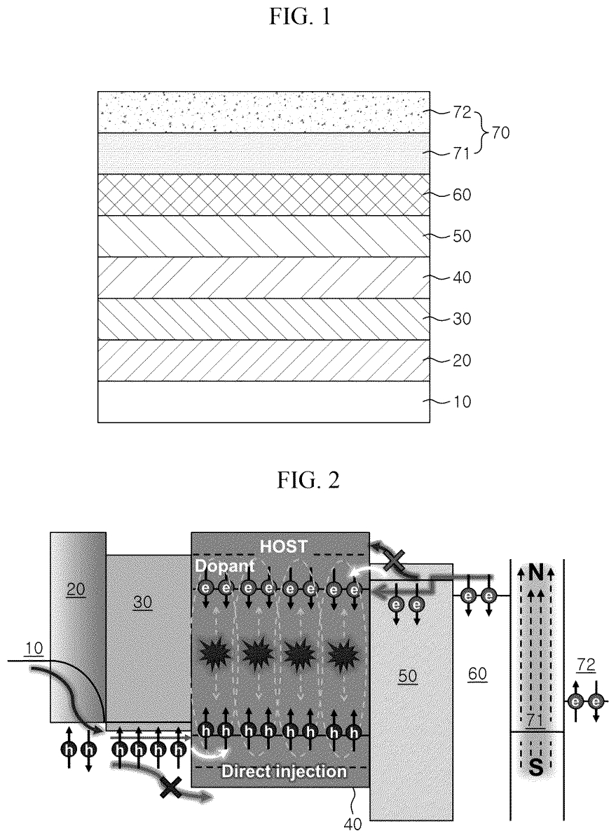

FIG. 1 is a cross-sectional view showing an organic light-emitting diode according to an embodiment of the present invention. FIG. 2 is a schematic diagram showing an energy band diagram of an organic light-emitting diode according to an embodiment of the present invention.

Referring to FIGS. 1 and 2, the organic light-emitting diode comprises an anode 10 and a cathode 70, an light-emitting layer 40 disposed between these two electrodes, a hole conduction layer disposed between the anode 10 and the light-emitting layer 40, and an electron conduction layer disposed between the light-emitting layer 40 and the cathode 70.

The anode 10 may be a conductive metal oxide, a metal, a metal alloy, or a carbon material. Conductive metal oxides may be indium tin oxide (ITO), fluorine tin oxide (FTO), antimony tin oxide (ATO), fluorine-doped tin oxide (FTO), SnO₂, ZnO, or combinations thereof. Suitable metals or metal alloys for the anode 10 may be Au and CuI. Carbon materials may be graphite, graphene, or carbon nanotubes.

The hole conduction layer may comprise a hole injection layer 20 and/or a hole transport layer 30. The hole injection layer 20 and/or hole transport layer 30 are layers having a HOMO (Highest Occupied Molecular Orbital) level between the work function level of the anode 10 and a HOMO level of the light-emitting layer 40, serving to enhance the efficiency of hole injection or transport from the anode 10 to the light-emitting layer 40. In one example, the hole injection layer 20 has a HOMO level similar to or lower (or deeper) than the work function of the anode 10, and the hole transport layer 30 may have a HOMO level between the HOMO level of the hole injection layer 20 and the HOMO level of the light-emitting layer 40. In this case, the HOMO level of the light-emitting layer 40 may be a HOMO level of a dopant within the light-emitting layer 40, as described in detail later.

The hole injection layer 20, for example, may comprise one or more selected from the group consisting of mCP (N,N-dicarbazolyl-3,5-benzene); PEDOT:PSS (poly(3,4-ethylenedioxythiophene): polystyrenesulfonate); NPD (N,N′-di(1-naphthyl)-N,N′-diphenylbenzidine); N,N′-diphenyl-N,N′-di(3-methylphenyl)-4,4′-diaminobiphenyl (TPD); N,N′-diphenyl-N,N′-dinaphthyl-4,4′-diaminobiphenyl; N,N,N′,N′-tetra-p-tolyl-4,4′-diaminobiphenyl; N,N,N′,N′-tetraphenyl-4,4′-diaminobiphenyl; porphyrin derivatives such as copper(II) 1,10,15,20-tetraphenyl-21H,23H-porphyrin; TAPC (1,1-Bis[4-[N,N′-Di(p-tolyl)Amino]Phenyl]Cyclohexane); triarylamine derivatives such as N,N,N-tri(p-tolyl)amine, 4,4′,4′-tris[N-(3-methylphenyl)-N-phenylamino]triphenylamine; carbazole derivatives such as N-phenylcarbazole and polyvinylcarbazole; phthalocyanine derivatives such as metal-free phthalocyanine and copper phthalocyanine; starburst amine derivatives; enaminostilbene derivatives; derivatives of aromatic tertiary amines and styryl amine compounds; and polysilanes.

In one example, the hole injection layer 20 may further include PFSA (Perfluorosulfonic acid), an ionomer in which sulfonic acid (—SO₃H) groups are attached to a perfluorinated polymer backbone, in addition to PEDOT:PSS. In this case, conductivity may be improved through increased rearrangement and crystallization of the PEDOT chains.

The hole transport layer 30 may comprise, as described above, a layer having a HOMO level between the work function level of the anode 10 or, if a hole injection layer 20 is included, the HOMO level of the hole injection layer 20 and the HOMO level of the light-emitting layer 40, and may be a spin-polarizing hole transport layer that spin-polarizes holes.

Specifically, the spin-polarizing hole transport layer 30 may be a layer having a Chiral Asymmetric Structure with one of either R-chirality or S-chirality, and can transfer spin-polarized holes to the light-emitting layer 40. Furthermore, the spin-polarizing hole transport layer 30 may exhibit Circular Dichroism (CD) due to its Chiral Asymmetric Structure.

In one example, the hole transport layer 30 having R-chirality can selectively conduct up spin by providing a lower resistance to up spin than to down spin, and the hole transport layer 30 having S-chirality can selectively conduct down spin by providing a lower resistance to down spin than to up spin. As such, the hole transport layer 30 having chirality can exhibit Chirality-Induced Spin Selectivity (CISS) due to the interaction between the helical structure of the chiral hole transport material and the Spin-Orbit Coupling (SOC) of the charge carriers. As a result, the hole transport layer 30 having chirality can transport spin-polarized holes to the light-emitting layer 40.

Furthermore, the hole transport layer 30 with R-chirality may absorb right-circularly polarized light (RCP) more than left-circularly polarized light (LCP), and the hole transport layer 30 with S-chirality may absorb left-circularly polarized light (LCP) more than right-circularly polarized light (RCP). Thus, the hole transport layer 30 having chirality may exhibit circular dichroism (CD).

The hole transport layer 30 with R-chirality may be an R-chiral metal-oxide layer, an R-chiral perovskite layer, or an R-chiral organic semiconductor layer. The hole transport layer 30 with S-chirality may be an S-chiral metal-oxide layer, an S-chiral perovskite layer, or an S-chiral organic semiconductor layer.

The chiral perovskite layer may include a perovskite having a chemical formula of ABX₃, A′₂Aₙ₋₁BX₃ₙ₊₁, ABX₄, A₂BX₄, A₂BX₅, A₃BX₅, A₄B₂X₁₀, ABX₅, A₃B₂X₉, AB₂X₁₀ or A₂B₁B′X₆, wherein the A may be an R- or S-chiral organic cation. When the A is an R-chiral organic cation, the chiral perovskite layer may be an R-chiral perovskite layer; when the A is an S-chiral organic cation, the chiral perovskite layer may be an S-chiral perovskite layer.

In one example, the A′ may be a chiral organic cation having a same chirality as the A but having a different composition. Specifically, when the A is an R-chiral organic cation, the A′ may also be an R-chiral organic cation, which is a material the same as or different from the A; and when the A is an S-chiral organic cation, the A′ may also be an S-chiral organic cation, which is a material the same as or different from the A. In another example, the A′ may be an achiral organic cation.

The B and the B′ may be, independently of each other, metal ions, achiral organic cations, inorganic cations, achiral ammonium ions, or combinations thereof. The X may be F⁻, Cl⁻, Br⁻, I⁻, or combinations thereof, and the n may be an integer from 1 to 10. The B and B′ may be, independently of each other, a metal ion selected from the group consisting of Pb, Sc, Ti, V, Cr, Mn, Fe, Co, Ni, Cu, Rb, Sr, Y, Zr, Nb, Mo, Tc, Ru, Rh, Pd, La, Ce, Pr, Nd, Tb, Dy, Ho, Er, Tm, Yb, Lu, Hf, Ta, W, Re, Os, Ir, Pt, Th, Pa, U, Pu, Am, Si, Zn, Ga, As, Se, Ag, Cd, In, Sn, Sb, Te, Au, Hg, Tl and Bi. In one example, the metal ion may be Pb or a metal ion other than Pb.

The chiral perovskite layer may have a structure where a coordination polyhedron layer and an A layer are alternately arranged. The coordination polyhedron layer may include coordination polyhedra having the structures of an BX₆ octahedron, an BX₅ square pyramid, an BX₄ tetrahedron, or an BX₄ square planar structure. The A layer may be coupled to the X within the coordination polyhedron layer via electrostatic attraction. Specifically, within the coordination polyhedron layer, the coordination polyhedra may be arranged by sharing corners to make a layered structure.

In one example, the chiral perovskite layer may be a two-dimensional (2D) layered perovskite layer and may include alternately stacked coordination polyhedral layers and organic layers (A layers). In one example, when the chiral perovskite layer has a chemical formula of A₂BX₄, the chiral perovskite layer may include a coordination polyhedral layer in which BX₆ octahedra are two-dimensionally arranged while sharing four corners (X ions) on the X-Y plane. Furthermore, two R- or S-form A layers, which are ionically bonded by electrostatic attraction to the two non-shared corners (X ions) on the Z-axis of each BX₆ octahedron, are respectively disposed on the upper and lower parts of the coordination polyhedral layer. When multiple coordination polyhedral layers are stacked, an R- or S-form A layer ionically bonded to the lower coordination polyhedral layer and an R- or S-form A layer ionically bonded to the upper coordination polyhedral layer are located between a pair of coordination polyhedral layers. These two R- or S-form A layers located between the pair of coordination polyhedral layers may constitute the organic layer. The coordination polyhedral layer may be a quantum well where charge carriers are confined, and the organic layer may be a barrier that is difficult for charge carriers to pass over. Therefore, the 2D layered perovskite layer may have a multi-quantum well (MQW) structure formed in the out-of-plane direction.

Meanwhile, the chirality of A is transferred to the coordination polyhedral layer by the electrostatic attraction, and thus the coordination polyhedral layer may also have an asymmetrically distorted structure. In other words, the bond angle and/or bond distance of B and X in the coordination polyhedral layer may change asymmetrically. As a result, if A is an R-chiral organic cation, the coordination polyhedral layer bonded to it by electrostatic attraction also acquires R-chirality; and if A is an S-chiral organic cation, the coordination polyhedral layer bonded to it by electrostatic attraction also acquires S-chirality. Consequently, the chiral perovskite layer may possess an R- or S-chirality by having a helical arrangement that twists either to the left or to the right within the crystal.

The chiral organic cation A may be a cation represented by the following Chemical Formula 1 or Chemical Formula 2, and may be distinguished into R-form and S-form based on the priority of R^{a}, R^{b}, and R^{c}. Furthermore, when A′ is a chiral organic cation, A′ may also be a cation represented by the following Chemical Formula 1 or Chemical Formula 2. The priority of R^{a}, R^{b}, and R^{c} may be determined using conventional methods employed in the art.

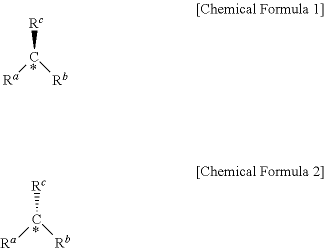

In Chemical Formulas 1 and 2, R^{a} and R^{b} may each independently be a substituted or unsubstituted C₁-C₁₀ alkyl, C₃-C₁₀ cycloalkyl, C₃-C₁₀ heterocycloalkyl, C₆-C₁₂ aryl, C₆-C₁₂ heteroaryl, or C₆-C₁₂ heteroaryl-C₁-C₁₀ alkyl, wherein the heterocycloalkyl or heteroaryl contains N, O, S, P, or Se in a ring, which may be different from each other or bonded together to form a ring.

R^{c} may be NH₃⁺, RNH₃⁺, (CH₂)ₘNH₃⁺, COOH, (CH₂)ₘCOOH, OH, or CH₃. When the R^{c} is COOH, (CH₂)ₘCOOH, OH or CH₃, a substituent of R^{a} may be RNH₃⁺, (CH₂)ₘNH₃⁺ or NH₃⁺, wherein R may be a substituted or unsubstituted C₁-C₁₀ alkyl, C₃-C₁₀ cycloalkyl, C₃-C₁₀ heterocycloalkyl, C₆-C₁₂ aryl, C₆-C₁₂ heteroaryl or C₆-C₁₂heteroarylC₁-C₁₀alkyl, wherein the heterocycloalkyl or heteroaryl contains N, O, S, P or Se in a ring. m may be an integer from 1 to 10. * represents a chiral central carbon.

In the above R^{a} and R^{b}, the cycloalkyl, heterocycloalkyl, aryl or heteroaryl may be substituted with halogen, C₁-C₂ alkyl or C₁-C₂ alkoxy.

For example, the chiral organic cation represented by Chemical Formula 1 may be the cation represented by the following Chemical Formula 1A, and the chiral organic cation represented by Chemical Formula 2 may be the cation represented by Chemical Formula 2A.

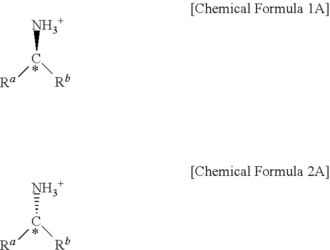

In Chemical Formulas 1A and 2A, R^{a}, R^{b}, and * are as defined in Chemical Formulas 1 and 2.

The chiral organic cation represented by Chemical Formula 1A or Chemical Formula 2A may be at least one selected from the following groups.

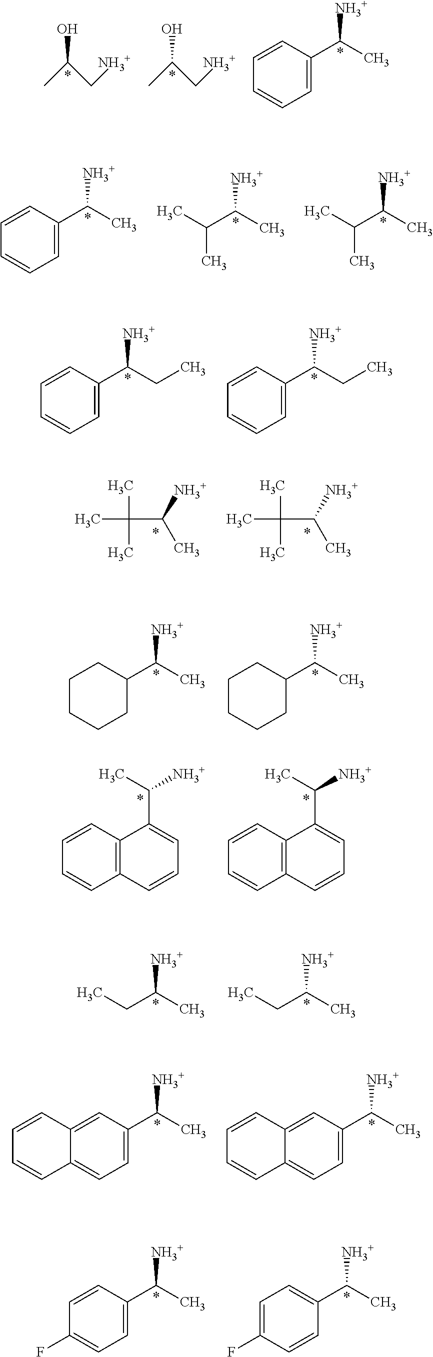

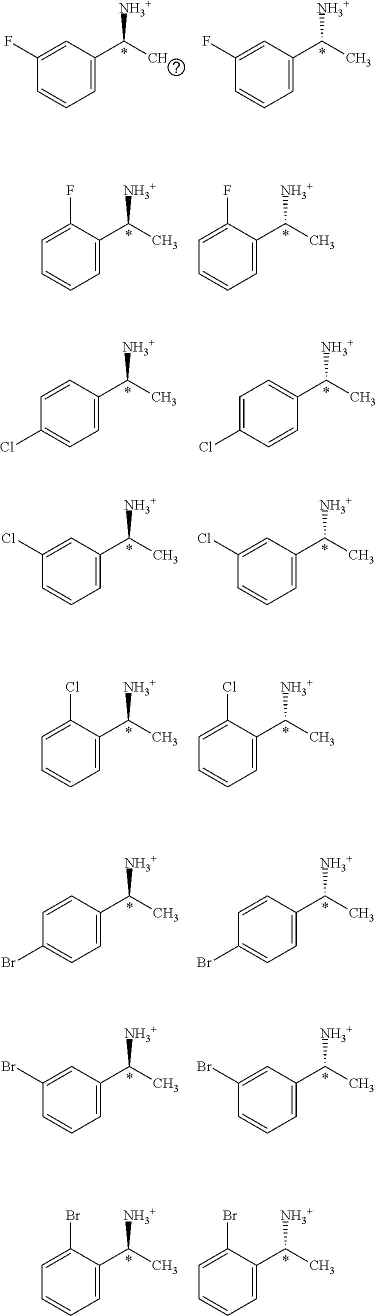

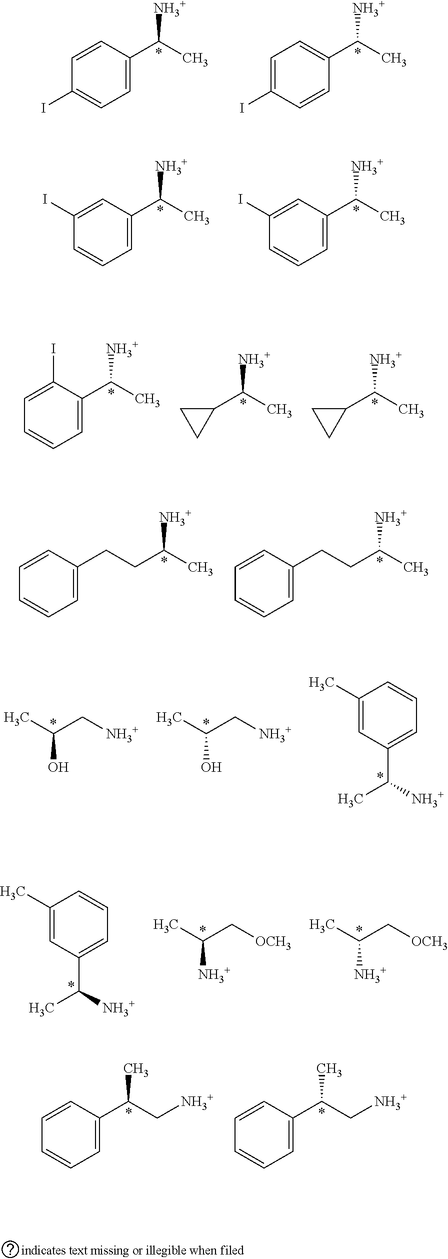

As another example, the chiral organic cation represented by Chemical Formula 1 may be the cation represented by the following Chemical Formula 1B, and the chiral organic cation represented by Chemical Formula 2 may be the cation represented by the following Chemical Formula 2B.

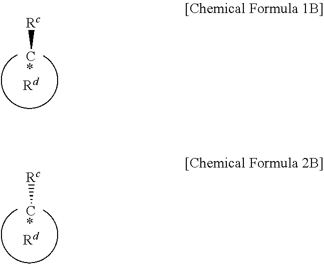

In Chemical Formulas 1B and 2B, R^{c} may be NH₃⁺, RNH₃⁺, (CH₂)ₘNH₃⁺, COOH, (CH₂)ₘCOOH, OH, or CH₃. R^{d} may be C₅-C₁₂ cycloalkyl or C₅-C₁₂ heterocycloalkyl which does not have a plane of symmetry based on the chiral center carbon, wherein the heterocycloalkyl contains N, O, S, P or Se in the ring, and the cycloalkyl or the heterocycloalkyl may be fused with C₆-C₁₂ aryl. When R^{c} is COOH, (CH₂)ₘCOOH, OH, or CH₃, R^{d} may have a member in the ring substituted with NH⁺ or NH₂⁺, or has a RNH₃⁺, (CH₂)ₘNH₃⁺, or NH₃⁺ substituent bonded to the ring, wherein R is a substituted or unsubstituted C₁-C₁₀ alkyl, C₃-C₁₀ cycloalkyl, C₃-C₁₀ heterocycloalkyl, C₆-C₁₂ aryl, C₆-C₁₂ heteroaryl, or C₆-C₁₂ heteroaryl-C₁-C₁₀ alkyl, wherein the heterocycloalkyl or heteroaryl contains N, O, S, P, or Se in a ring. m may be an integer from 1 to 10, and * represents a chiral central carbon.

The chiral organic cation of Chemical Formula 1B or Chemical Formula 2B may be at least one selected from the following group or a combination thereof.

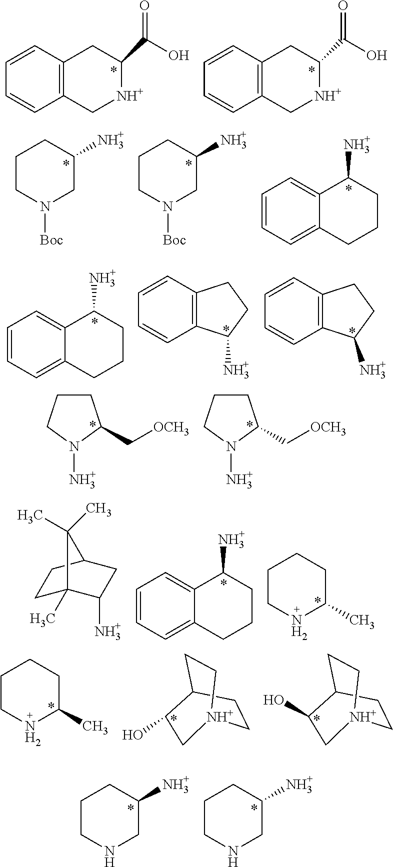

The above achiral organic cation may be R_{c}NH₃⁺, and Re may be C₁-C₆ alkyl or C₁-C₆ haloalkyl.

The chiral metal-oxide layer may have a material in which a chiral organic material is formed between a metal-oxide crystals, causing the metal-oxide crystals to exhibit Circular Dichroism (CD) due to a chiral transfer phenomenon. Specifically, the chiral metal-oxide layer may be a layer that is surface-functionalized by a chiral ligand or chiral organic molecule. In this case, if the chiral ligand or chiral organic molecule has R-chirality, the chiral metal-oxide layer is an R-chiral metal-oxide layer; and if the chiral ligand or chiral organic molecule has S-chirality, the chiral metal-oxide layer is an S-chiral metal-oxide layer.

In another example, the chiral metal-oxide layer may be formed to have nanostructural asymmetry (chirality), thereby exhibiting R-chirality or S-chirality. Specifically, the chiral metal-oxide layer may be synthesized to have a helical or spiral arrangement, or the chiral metal-oxide layer may be formed to have nanocolumns, nanotwists, or screw-like nanostructures created by anisotropic deposition, substrate rotation or glancing angle deposition (GLAD), or substrate patterning. Through these structures, the surface or bulk of the metal-oxide structure may exhibit R- or S-form selective chirality on a macroscopic or microscopic scale.

The metal-oxide may include one or more selected from TiOₓ (x is a real number from 1 to 3), indium oxide (In₂O₃), tin oxide (SnO₂), zinc oxide (ZnO), zinc tin oxide (Zinc Tin Oxide), gallium oxide (Ga₂O₃), tungsten oxide (WO₃), aluminum oxide, titanium oxide, vanadium oxide (V₂O₅, VO₂, V₄O₇, V₅O₉, V₂O₃), molybdenum oxide (MoO₃ or MoOₓ), copper oxide (Copper(II) Oxide: CuO), nickel oxide (NiO), copper aluminum oxide (Copper Aluminium Oxide: CAO, CuAlO₂), zinc rhodium oxide (Zinc Rhodium Oxide: ZRO, ZnRh₂O₄), iron oxide, chromium oxide, bismuth oxide, IGZO (indium-Gallium Zinc Oxide), and ZrO₂.

The chiral organic semiconductor layer may include a π-conjugated polymer or low-molecular-weight compound containing a chiral center or having a chiral auxiliary group, such as polyfluorene-based polymers introduced with chiral vinyl derivatives, (R)- or (S)-1-phenylethanol, (R) or (S)-binallyl, chiral PEDOT, or chiral pyrene derivatives.

The cathode 70 may include a ferromagnetic metal layer 71. The cathode 70 may further include a cathode conductive film 72 in addition to the ferromagnetic metal layer 71. The cathode conductive film 72 may be a conductive film having a work function lower than that of the anode 10, for example, it may be formed using metals such as aluminum, magnesium, calcium, sodium, potassium, indium, yttrium, lithium, silver, lead, cesium, or a combination of two or more of these metals. Although not shown, the cathode 70 may include not only the cathode conductive layer 72 formed on top of the ferromagnetic metal layer 71, but also another cathode conductive layer formed beneath the ferromagnetic metal layer 71.

The ferromagnetic metal layer 71 may be a metal layer capable of exhibiting strong ferromagnetism due to the alignment of electron spin directions, and may be Fe, Ni, Co, FeCo, NiFe, or a composite film thereof. The ferromagnetic metal layer 71 may act as a spin filter that selectively transmits electrons with a specific spin direction, thereby enabling the generation of spin-polarized current. To elaborate, the ferromagnetic metal layer 71 may selectively conduct spin-polarized electrons depending on its magnetization direction. For example, a ferromagnetic metal layer 71 magnetized in the up direction provides lower resistance to up spins than to down spins, enabling selective conduction of up spins. while a ferromagnetic metal layer 71 magnetized in the down direction provides lower resistance to down spins than to up spins, enabling selective conduction of down spins.

The electron conduction layer disposed between the light-emitting layer 40 and the cathode 70 may include an electron injection layer 60 and/or an electron transport layer 50. The electron injection layer 60 and/or the electron transport layer 50 may be layers having a LUMO level between the work function level of the cathode 70, specifically the cathode conductive film 72, and the LUMO level of the light-emitting layer 40, and may function to increase the efficiency of electron injection or transport from the cathode 70 to the light-emitting layer 40. In one example, the electron injection layer 60 may have a LUMO level similar to or higher (shallower) than the work function of the cathode 70, specifically the cathode conductive film 72, and the electron transport layer 50 may have a LUMO level between the LUMO level of the electron injection layer 60 and the LUMO level of the light-emitting layer 40. In this case, the LUMO level of the light-emitting layer 40 may be the LUMO level of a dopant in the light-emitting layer 40, as will be described in detail later.

In addition, the electron transport layer 50 may also function as a hole blocking layer by having a HOMO level that is very low (deep) compared to the HOMO level of the light-emitting layer 40, specifically, the HOMO level of the dopant. In this case, holes can be trapped within the light-emitting layer 40 to allow electrons and holes to recombine efficiently.

The electron injection layer 60 may be, for example, LiF, NaCl, CsF, Li₂O, BaO, BaF₂, or Liq (lithium quinolate). The electron transport layer 50 may be TSPO1 (diphenylphosphine oxide-4-(triphenylsilyl)phenyl), TPBi (1,3,5-tris(N-phenylbenzimidazol-2-yl)benzene), tris(8-quinolinolate)aluminum (Alq₃), 2,5-diaryl silyl derivatives (PyPySPyPy), perfluorinated compounds (PF-6P), COTs (Octasubstituted cyclooctatetraene), Bphen (4,7-diphenyl-1,10-phenanthroline).

In one example, the light-emitting layer 40 may include a host and a dopant. The host may prevent concentration quenching between dopant molecules. In another example, the light-emitting layer 40 may include a single emissive material. The light-emitting layer 40 may be a fluorescent or phosphorescent light-emitting layer.

The host may have a larger band gap than the dopant. The energy level of the HOMO or valence band maximum (VBM) of the host may be lower than the energy level of the HOMO or VBM of the dopant, and the energy level of the LUMO or conduction band minimum (CBM) of the host may be higher than the energy level of the LUMO or CBM of the dopant.

Since the energy level of the HOMO or the VBM of the dopant is similar to, slightly lower than, or higher than the HOMO energy level of the hole transport layer 30, spin-polarized holes injected through the hole transport layer 30 can be directly injected into the dopant. On the other hand, since the energy level of the HOMO or the VBM of the host is much lower than the HOMO energy level of the hole transport layer 30, an energy barrier may be created, so spin-polarized holes injected through the hole transport layer 30 may have difficulty being injected into the host. In this way, spin-polarized holes injected through the hole transport layer 30 are blocked by the energy barrier of the host and are not injected into the host, and are directly injected into the dopant while maintaining the spin phase, so that the spin dephasing probability can be reduced compared to when transferred through the host.

In addition, the energy level of the LUMO or the CBM of the dopant is similar to, slightly higher than, or lower than the LUMO energy level of the electron conduction layer, specifically the electron transport layer 50, so that spin-polarized electrons which are spin-polarized by the ferromagnetic metal layer 71 and injected through the electron transport layer 50 can be directly injected into the dopant. On the other hand, the energy level of the LUMO or the CBM of the host is much higher than the LUMO energy level of the electron conduction layer, specifically the electron transport layer 50, so that an energy barrier is created, so that it may be difficult for spin-polarized electrons injected through the electron transport layer 50 to be injected into the host. In this way, spin-polarized electrons are blocked by the energy barrier of the host and are not injected into the host, and are directly injected into the dopant of the light-emitting layer 40 while maintaining the spin phase, so that the spin dephasing probability can be reduced compared to when transferred through the host.

In this way, spin-polarized holes and spin-polarized electrons transported from the hole transport layer 30 and the electron transport layer 50, respectively, can be directly injected into the HOMO and LUMO of the dopant, respectively, rather than being transferred to the dopant via the host within the light-emitting layer 40. The electrons and holes directly injected by the dopant can combine at the dopant to form an exciton, after which the exciton can emit light as it transitions to the ground state.

The host may include at least one selected from Alq₃, CBP (4,4′-Bis(carbazol-9-yl)biphenyl), ADN (9,10-di(naphthalene-2-yl)anthracene), TCTA (tris(4-carbazoyl-9-ylphenyl)amine), TAPC (1,1′-Bis[(di-4-tolylamino)phenyl]cyclohexane), TPBI (1,3,5-Tris(1-phenyl-1H-benzimidazol-2-yl)benzene), TBADN (3-tert-Butyl-9,10-di(naphthalen−2-yl)anthracene), BeBq₂, 2PTPS (diphenylbis(3-(pyridine-2-yl)phenyl)silane), 3PTPS (diphenylbis(3-(pyridine-3-yl)phenyl)silane), 4PTPS (diphenylbis(3-(pyridine-4-yl)phenyl)silane). The host may be a single host or a mixed host of a hole-transporting host and an electron-transporting host. If the host is a mixed host, refer to FIG. 4.

The dopant may be a fluorescent or phosphorescent dopant.

If the dopant is a fluorescent dopant, the organic light-emitting diode according to the present embodiment may be referred to as a fluorescent organic light-emitting diode.

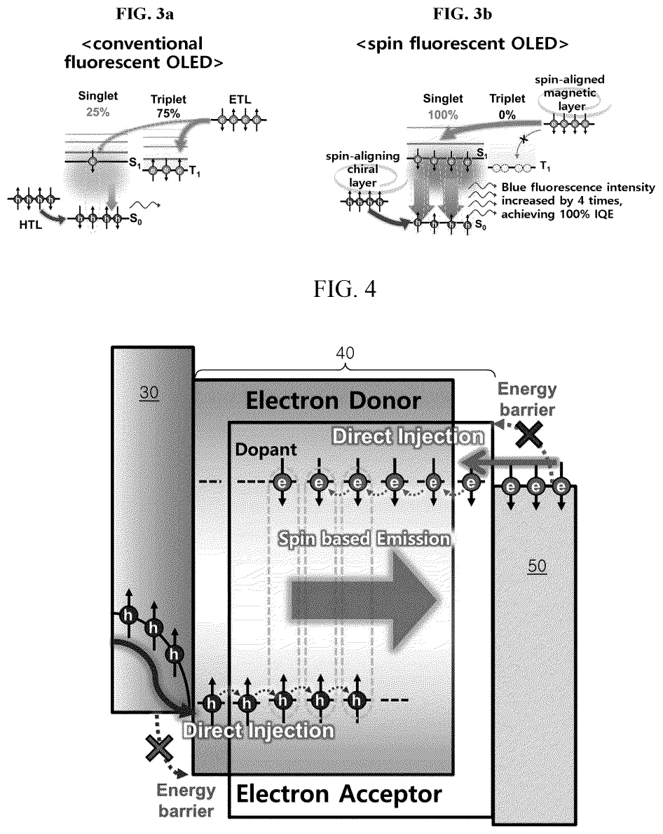

FIGS. 3a and 3b are schematic diagrams showing the emission mechanisms of a conventional fluorescent organic light-emitting diode and a fluorescent organic light-emitting diode according to an embodiment of the present invention, respectively.

In the conventional fluorescent organic light-emitting device illustrated in FIG. 3a, since the spins of electrons and holes are injected into a light-emitting layer in a non-polarized state, only 25% of the excitons resulting from the electron and hole combination within the light-emitting layer can be singlet excitons. Therefore, the theoretical internal quantum efficiency of the fluorescent organic light-emitting diode cannot exceed 25%.

However, referring to FIGS. 2 and 3b simultaneously, in the case of the fluorescent organic light-emitting diode according to one embodiment of the present invention, spin-polarized holes having up spin or down spin that are selectively conducted through the hole transport layer 30 flow into the light-emitting layer 40, and electrons having a spin state opposite to the spin state of the holes selectively conducted through the hole transport layer 30 are selectively conducted through the ferromagnetic cathode 71 and can be transported to the light-emitting layer 40 via the electron conduction layer, specifically, the electron injection layer 60 and/or the electron transport layer 50. In this case, electrons and holes having spin states in opposite directions can combine within the light-emitting layer 40, so that the ratio of singlet excitons among the excitons generated by the combination of electrons and holes can exceed 25% and even reach up to 100%. In other words, singlet excitons can advance at a higher rate than triplet excitons, theoretically reaching 100% formation. Specifically, the singlet excitons can be formed at a higher ratio compared to the triplet excitons, reaching theoretically up to 100%. Thus, the internal quantum efficiency of a fluorescent organic light-emitting diode according to one embodiment of the present invention can be significantly improved to exceed 25% and even up to 100%.

The fluorescent dopant may be a blue fluorescent dopant, and may include a polymeric light-emitting body having a fluorescent functional group attached (grafted) to a non-conjugated polymer, a derivative or copolymer of conjugated polymer such as polyfluorene, polyspirofluorene, poly(p-phenylene vinylene), poly(p-phenylene), polythiophene, and polycarbazole, and a light-emitting body including a light-emitting material. As another example, the fluorescent dopant may be a blue fluorescent dopant such as DPVBi (4,4′-Bis(2,2-diphenylvinyl)-1,1′-biphenyl), TC-1 (2,7-Bis(4-(9H-carbazol-9-yl)phenyl)-9H-thioxanthen−9-one), TC-2 (3,7-Bis(4-(9H-carbazol-9-yl)phenyl)dibenzo[b,d]thiophene 5,5-dioxide), TC-3 (3,7-Bis(9-phenyl-9H-carbazol-3-yl)dibenzo[b,d]thiophene 5,5-dioxide), PTPATPPO, PTPATPP, ((Ca, Ba, Sr)₁₀(PO₄)₆Cl₂:Eu²⁺), SH-1, BD-1, BD-2, BD-3, BD-4, and additionally, 2CzPN, 4TCzBN, TDBA-Cz, diphenylaminovinylbiphenyl (DPAVBi), tetraphenylbutadiene (TBPe), etc.

When the dopant is a phosphorescent dopant, the organic light-emitting diode according to an embodiment of the present invention may be referred to as a phosphorescent organic light-emitting diode.

When the dopant is a phosphorescent dopant, spin-polarized holes having up or down spins are selectively conducted through the hole transport layer 30 and transferred into the light-emitting layer 40, and electrons having the same spin state as the holes selectively conducted through the hole transport layer 30 are selectively conducted through the ferromagnetic cathode 71 and transported to the light-emitting layer 40 via the electron-conduction layer, specifically, the electron injection layer 60 and/or the electron transport layer 50. In this case, electrons and holes having spin states in the same direction can combine within the light-emitting layer 40, so that triplet excitons can theoretically be formed 100%.

The phosphorescent dopant may be a blue phosphorescent dopant such as FIrpic (Bis(4,6-difluorophenyl-pyridinate) iridium(III)), Ir(fdpt)₃ (tris(2-(2,4-difluorophenyl)pyridine)iridium(III)), Ir(dpt)₃ (Tris(2-phenylpyridine)iridium(III)), Ir(2-phq)₂(acac) (Iridium(III) bis(2-phenylquinoline)(acetylacetonate)), mer-Ir1 (mer-tris(N-phenyl, N-benzyl-pyridoimidazol-2-yl)iridium(III)), PtON-tb-DTB, calcium phosphate (calcium phosphate chloride: europium(II), Ca₂-xPO₄Cl:Euₓ²⁺), TADF (Thermally Activated Delayed Fluorescence)-based phosphors, and additionally, Ir(dfppy) (3Tris[2-(2,4-difluorophenyl)pyridine]iridium(III)), (F₂ppy)₂Ir(tmd), iridium(III) tri(difluorophenylpyridine)(Ir(dfppz)₃), Tris(2-phenylpyridine)iridium(III) (Ir(ptz)₃), etc., but is not limited thereto.

FIG. 4 is a schematic diagram showing an energy band diagram of an organic light-emitting diode according to an embodiment of the present invention when a host in a light-emitting layer is a mixed host.

Referring to FIGS. 2 and 4 simultaneously, the host in the light-emitting layer 40 may be a mixed host of a hole-transporting host and an electron-transporting host. The hole-transporting host may be referred to as an electron donor, and the electron-transporting host may be referred to as an electron acceptor. In this case, the mobility of electrons and holes within the light-emitting layer 40 can be balanced. In addition, the formation of an exciplex between the two hosts can be prevented by increasing the energy level difference between the hole-transporting host and the electron-transporting host or by using materials for the two hosts that do not interact with each other.

These mixed hosts may include CBP (4,4′-Bis(N-carbazolyl)-1,1′-biphenyl), 2PTPS (diphenylbis(3-(pyridine-2-yl)phenyl)silane), 3PTPS (diphenylbis(3-(pyridine-3-yl)phenyl)silane), or 4PTPS (diphenylbis(3-(pyridine-4-yl)phenyl)silane) as the electron donor, and TPBI (1,3,5-tris(N-phenylbenzimiazole-2-yl)benzene) or TCTA (4,4′,4″-tris(N-carbazolyl)-triphenylamine) as the electron acceptor. Specifically, the mixed host may be CBP:TPBI, 2PTPS:TCTA, 3PTPS:TCTA, or 4PTPS:TCTA.

The electron donor and electron acceptor may have a larger band gap than the dopant. The energy level of the HOMO or the valence band maximum (VBM) of the electron donor and electron acceptor may be lower than the energy level of the HOMO or the VBM of the dopant, and the energy level of the LUMO or the conduction band minimum (CBM) of the electron donor and electron acceptor may be higher than the energy level of the LUMO or the CBM of the dopant.

The energy level of HOMO or VBM of the electron donor as well as the electron acceptor is much lower than the HOMO energy level of the hole transport layer 30, thereby creating an energy barrier, so that spin-polarized holes injected through the hole transport layer 30 may have difficulty being injected into the electron donor and further into the electron acceptor. On the other hand, as described above, the energy level of HOMO or VBM of the dopant is similar to, slightly lower than, or higher than the HOMO energy level of the hole transport layer 30, so that spin-polarized holes injected through the hole transport layer 30 can be directly injected into the dopant. In this way, the spin-polarized holes injected through the hole transport layer 30 are directly injected into the dopant while maintaining the spin phase, so the spin dephasing probability can be reduced compared to when transferred to the dopant through the electron donor.

In addition, since the energy level of LUMO or CBM of the electron donor as well as the electron acceptor is much higher than the LUMO energy level of the electron transport layer 50, thereby creating an energy barrier, it may be difficult for spin-polarized electrons injected through the electron transport layer 50 to be injected into the electron acceptor and further into the electron donor. On the other hand, as described above, the energy level of LUMO or CBM of the dopant is similar to, slightly higher than, or lower than the LUMO energy level of the electron transport layer 50, so that spin-polarized electrons, which are spin-polarized by the ferromagnetic metal layer 71 and injected through the electron transport layer 50, can be directly injected into the dopant. In this way, the spin-polarized electrons can be directly injected into the dopant of the light-emitting layer 40 while maintaining the spin phase, thereby reducing the probability of spin dephasing compared to when transferred to the dopant through the host.

In this way, spin-polarized holes and spin-polarized electrons transported from the hole transport layer 30 and electron transport layer 50, respectively, can be directly injected into the HOMO and LUMO of the dopant, respectively, with the spin phase maintained, rather than being transferred to the dopant via the host within the light-emitting layer 40. The electrons and holes directly injected into the dopant may combine in the dopant to form excitons. Since the spin-polarized electrons and spin-polarized holes combine with the spin phase maintained to generate excitons, the generated excitons may theoretically be singlet excitons up to 100% or triplet excitons up to 100%. Thereafter, the excitons are transferred to the ground state and emit light, so that the internal quantum efficiency can be improved to up to 100%.

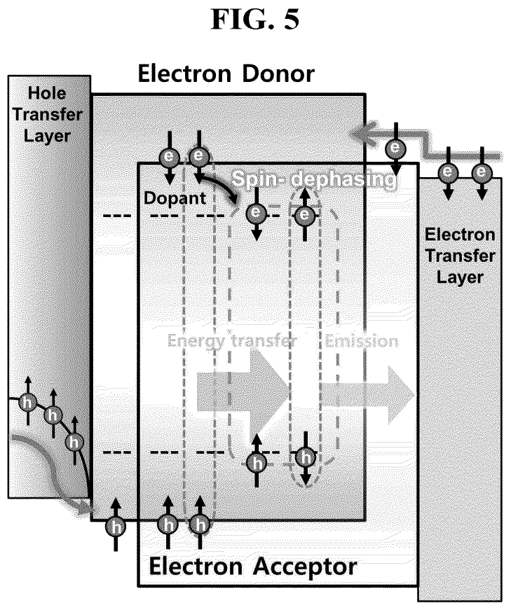

FIG. 5 schematically illustrates the phenomenon observed when no energy barrier forms between the HOMO of the electron donor and the HOMO of the hole transport layer, and when no energy barrier forms between the LUMO of the electron acceptor and the LUMO of the electron transport layer.

Referring to FIG. 5, when the energy barrier between the HOMO of the electron donor and the HOMO of the hole transport layer is not formed since the energy level of the HOMO or the VBM of the electron donor is slightly lower than the HOMO energy level of the hole transport layer, at least some of the spin-polarized holes injected through the hole transport layer can be injected into the electron donor; and when the energy barrier between the LUMO of the electron acceptor and the LUMO of the electron transport layer is not formed since the energy level of the LUMO or the CBM of the electron acceptor is slightly higher than the LUMO energy level of the electron transport layer, at least some of the spin-polarized electrons injected through the electron transport layer can be injected into the electron acceptor. The spin-polarized holes injected into the electron donor can undergo spin dephasing upon transfer to the dopant, and the spin-polarized electrons injected into the electron acceptor can undergo spin dephasing upon transfer to the dopant. Such spin dephasing facilitates the co-generation of singlet and triplet excitons, which may make it difficult to improve the luminous efficiency of organic light-emitting diodes.

In another example, the light-emitting layer 40 may include a single light-emitting material rather than the host and the dopant. The single light-emitting material may be a fluorescent material. In this case, since electrons and holes are directly injected into the LUMO and HOMO of the single light-emitting material, triplet excitons are suppressed and singlet excitons can be theoretically formed 100%. To this end, the energy level of the HOMO or the VBM of the single light-emitting material is equal to or slightly lower than the HOMO energy level of the hole transport layer, so that holes with aligned spins injected through the hole transport layer can be directly injected into the single light-emitting material while maintaining their spin phase. In addition, since the energy level of the LUMO or the CBM of the single light-emitting material is equal to or slightly higher than the LUMO energy level of the electron injection layer, the spin phase of electrons with aligned spins injected through the electron injection layer can be directly injected into the single light-emitting material while maintaining the spin phase.

Such a single luminescent material may be a derivative or copolymer of a conjugated polymer such as polyfluorene, polyspirofluorene, poly(p-phenylene vinylene), poly(p-phenylene), polythiophene, or polycarbazole. In another example, the single luminescent material may be a grafted polymeric single luminescent material having a fluorescent functional group attached to a non-conjugated polymer.

The anode 10, the ferromagnetic metal layer 71, and the cathode conductive film 72 can be formed independently of each other using sputtering, vapor deposition, or ion beam deposition. The hole injection layer 20, the hole transport layer 30, the light-emitting layer 50, the electron transport layer 50, and the electron injection layer 60 can be formed independently of each other using a deposition or coating method, such as spraying, spin coating, dipping, printing, doctor blading, or electrophoresis. In one example, the hole injection layer 20 can be formed using spin coating after dissolving an R- or S-chiral crystal in a solvent.

The organic light-emitting diode can be disposed on a substrate (not shown), which can be disposed under the anode 10 or over the cathode 70. In other words, the anode 10 may be formed on the substrate before the cathode 70, or the cathode 70 may be formed before the anode 10.

The substrate may be a flat member that is transparent to light, and in this case, the substrate may be made of glass; a ceramic material; or a polymer material such as polycarbonate (PC), polyethylene terephthalate (PET), polyethylene naphthalate (PEN), polyimide (PI), or polypropylene (PP). However, the substrate is not limited thereto, and the substrate may also be a metal substrate capable of reflecting light.

When a forward bias is applied to such an organic light-emitting diode, holes are transferred from the anode 10 into the light-emitting layer 40, and electrons are transferred from the cathode 70 into the light-emitting layer 40. The electrons and holes that are transferred into the light-emitting layer 40 may combine to form excitons, and light is emitted when the excitons transition to the ground state.

Hereinafter, preferred manufacturing examples and experimental examples are presented to aid in understanding the present invention. However, the following manufacturing examples and experimental examples are provided solely to aid in understanding the present invention and are not intended to limit the present invention.

### Manufacturing Example 1A: Formation of an ITO/R-MBA₂PbI₄ Structure

An ITO substrate which is a glass substrate coated with an ITO anode was prepared. A solution of an R-MBA₂PbI₄ (MBA: Methylbenzylammonium) single crystal dissolved in dimethylformamide was spin-coated onto the ITO anode to form a spin-polarized hole transport layer.

### Manufacturing Example 1B: Formation of an ITO/S-MBA₂PbI₄ Structure

A structure including a spin-polarizing hole transport layer was formed using the same method as in Manufacturing Example 1A, except that an S-MBA₂PbI₄ single crystal was used instead of the R-MBA₂PbI₄ single crystal.

### Manufacturing Example 2A: Formation of an ITO/m-PEDOT:PSS/R-MBA₂PbI₄ Structure

An ITO substrate which is a glass substrate coated with an ITO anode was prepared. A mixed solution of PEDOT:PSS (AI4083, Heraeus), which is a conductive material, and PFI (PerFluorinated Ionomer which is perfluorosulfonic acid (PFSA) polymer dispersion) (D520, Dupont), was spin-coated onto the ITO anode. The solution was heat-treated at 150° C. for 30 minutes to form an approximately 40 nm-thick m-PEDOT:PSS hole-injection layer. A solution of R-MBA₂PbI₄ (MBA: methylbenzylammonium) single crystals dissolved in dimethylformamide was then spin-coated onto the hole-injection layer to form a spin-polarizing hole-transport layer approximately 30 nm thick.

### Manufacturing Example 2B: Formation of an ITO/m-PEDOT:PSS/S-MBA₂PbI₄ Structure

A structure including a spin-polarizing hole-transport layer was formed using the same method as in Manufacturing Example 2A, except that an S-MBA₂PbI₄ single crystal was used instead of the R-MBA₂PbI₄ single crystal.

### Manufacturing Example 3A: Formation of an ITO/m-PEDOT:PSS/R-MBA₂PbI₄/Light-Emitting Layer Structure

The structure obtained from Manufacturing Example 2A was spin-coated with a fluorescent material, Super Yellow polymer (Poly(p-phenylene vinylene (PPV) polymer, Livilux® PDY-132, Merck), dissolved in toluene, to form a light-emitting layer.

### Manufacturing Example 3B: Formation of an ITO/Hole Injection Layer/S-MBA₂PbI₄/Light-Emitting Layer Structure

The structure was formed using the same method as in Manufacturing Example 3A, except that the structure obtained from Manufacturing Example 2B was used instead of the structure obtained from Manufacturing Example 2A.

### <Spin-Polarized Current Measurement Example>

A magnetic conductive probe-atomic force microscope (mCP-AFM) tip was positioned on top of one of the structures according to Manufacturing Examples 1A, 1B, 2A, 2B, 3A, and 3B. Current-voltage characteristics were measured between the ITO electrode and the AFM tip when a magnetic field was applied to the mCP-AFM tip using a magnet to magnetize the tip in the positive (Tipup) or negative (Tip_{down}) direction, or when the tip was not magnetized (Tipo) due to no magnetic field applied to the mCP-AFM tip.

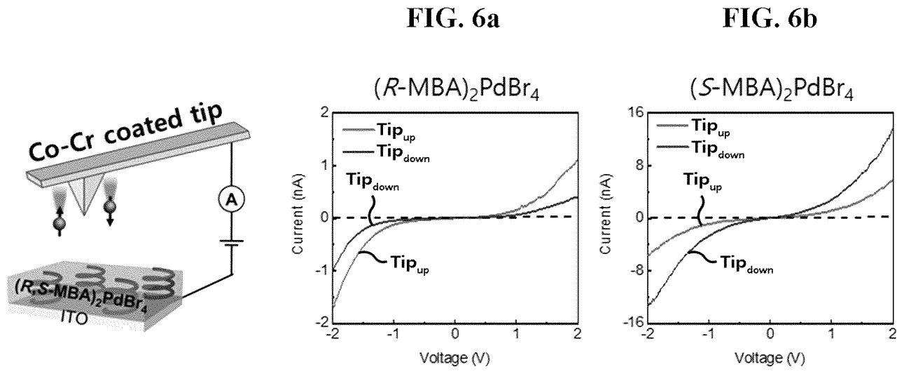

FIGS. 6a and 6b show graphs representing the spin-polarized currents of the structures according to Manufacturing Example 1A and Manufacturing Example 1B, respectively.

Referring to FIG. 6a, it can be seen that the structure of Manufacturing Example 1A, which includes R-MBA₂PbI₄, selectively conducts spin-polarized current in the + direction (Tipᵤₚ) compared to spin-polarized current in the − direction (Tip_{down}).

On the other hand, Referring to FIG. 6b, it can be seen that the structure of Preparation Example 1B, which includes S-MBA₂PbI₄, selectively conducts spin-polarized current in the − direction (Tip_{down}) compared to spin-polarized current in the + direction (Tipᵤₚ).

From FIGS. 6a and 6b, it can be seen that the R-type chiral perovskite layer selectively conducts one spin among up spin and down spin, and the S-type chiral perovskite layer selectively conducts the other spin among up spin and down spin.

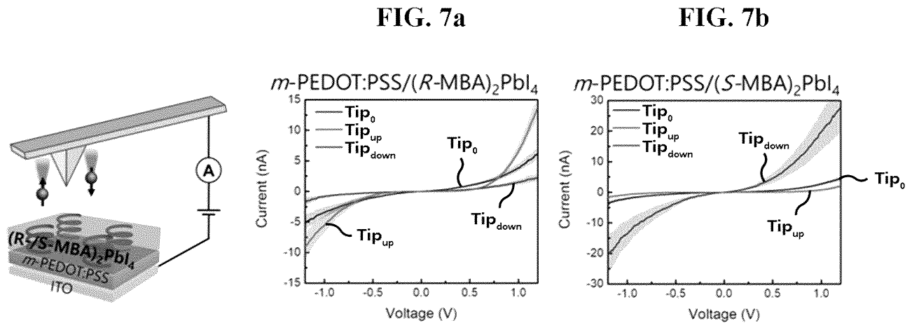

FIGS. 7a and 7b show graphs representing the spin-polarized currents of the structures according to Manufacturing Example 2A and Manufacturing Example 2B, respectively.

Referring to FIG. 7a, the structure of Manufacturing Example 2A, which includes R-MBA₂PbI₄, selectively conducts spin-polarized current in the + direction (Tipᵤₚ) compared to spin-unpolarized current (Tipo) or spin-polarized current in the − direction (Tip_{down}).

On the other hand, Referring to FIG. 7b, the structure of Manufacturing Example 2B, which includes S-MBA₂PbI₄, selectively conducts spin-polarized current in the − direction (Tip_{down}) compared to spin-unpolarized current (Tipo) or spin-polarized current in the + direction (Tipᵤₚ).

From FIGS. 7a and 7b, it can be seen that even when an m-PEDOT/PSS layer is interposed as a hole transport layer between the ITO electrode and the chiral perovskite layer, the R-type chiral perovskite layer selectively conducts one spin among the up spin and the down spin, and the S-type chiral perovskite layer selectively conducts the other spin among the up spin and the down spin.

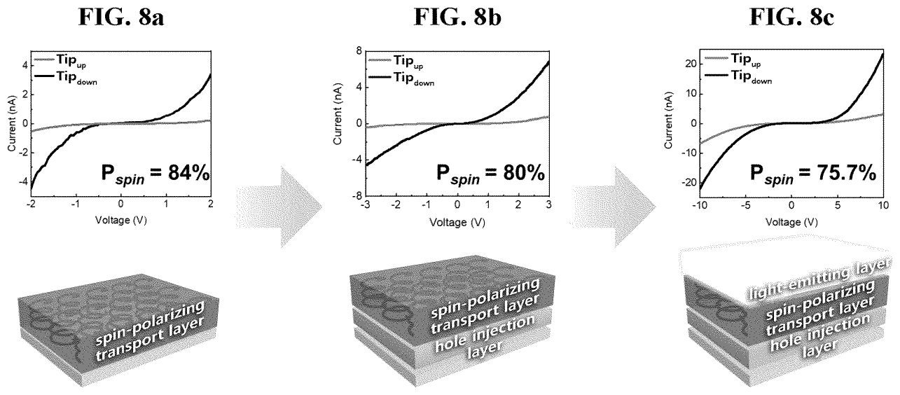

FIGS. 8a, 8b, and 8c show graphs representing the spin-polarized current of the structures according to Manufacturing Example 1A, Manufacturing Example 2A, and Manufacturing Example 3A, respectively.

Referring to FIGS. 8a, 8b, and 8c, it can be seen that the structures according to Manufacturing Example 1A, Manufacturing Example 2A, and Manufacturing Example 3A, which contain R-MBA₂PbI₄, all selectively conduct spin polarization current in the + direction (Tipᵤₚ) compared to spin polarization current in the − direction (Tip_{down}). In addition, the spin polarization (Pₛₚᵢₙ) was calculated based on the current difference in the + direction (Tipᵤₚ) and − direction (Tip_{down}). It was confirmed that an excellent spin polarization efficiency of 75.7% was maintained even when an m-PEDOT/PSS layer was included as a hole injection layer between the ITO electrode and the R-MBA₂PbI₄ chiral perovskite layer, which is a spin-polarizing hole transport layer, and a light-emitting layer was formed on the R-MBA₂PbI₄ chiral perovskite layer.

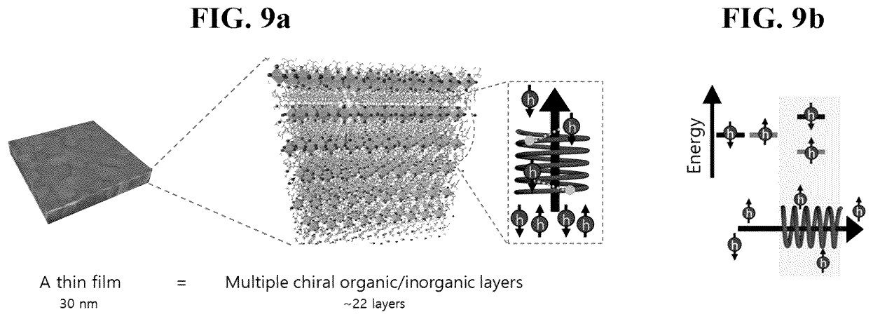

FIGS. 9a and 9b are schematic diagrams illustrating, respectively, the structure of the spin-polarizing hole transport layer and the Chirality-Induced Spin Selectivity (CISS) exhibited therethrough.

Referring to FIGS. 9a and 9b, when the spin-polarizing hole transport layer, an R- or S-MBA₂PbI₄ layer, is formed to a thickness of approximately 30 nm, the R- or S-MBA₂PbI₄ layer can have approximately 22 unit layers. Specifically, the R- or S-MBA₂PbI₄ may have a two-dimensional layered perovskite structure and comprise alternating inorganic and organic layers, and the unit layer may comprise a pair of inorganic and organic layers. Specifically, R- or S-MBA₂PbI₄ may have a coordination polyhedron layer, i.e., an inorganic layer, in which PbI₆ octahedra are two-dimensionally arranged while sharing four vertices (I ions) on the X-Y plane. In addition, two R- or S-MBA(methylbenzylammonium) ion layers, which are ionically bonded to two non-shared vertices (I ions) on the Z-axis of each PbI₆ octahedra, may be respectively disposed on the upper and lower portions of the coordination polyhedron layer by electrostatic attraction. When a plurality of coordination polyhedron layers are laminated, an R- or S-MBA ion layer ionically bonded to the lower coordination polyhedron layer and an R- or S-MBA ion layer ionically bonded to the upper coordination polyhedron layer are located between a pair of coordination polyhedron layers, and these two layers of R- or S-MBA ion layers located between a pair of coordination polyhedron layers can constitute the organic layer. The inorganic layer may be a quantum well in which charge carriers are trapped, and the organic layer may be a barrier that is difficult for the charge carriers to cross, so that the MBA₂PbI₄ layer may have a multi-quantum well structure formed in the out-of-plane direction.

The R- or S-chirality of the MBA ionic layer may be transferred to the coordination polyhedron layer by the electrostatic attraction, so that the coordination polyhedron layer may also have an asymmetrically distorted structure, i.e., the bond angle and/or bond distance between Pb and I may change asymmetrically. As a result, when MBA is R-MBA, the coordination polyhedron layer bonded to it by electrostatic attraction may also have R-chirality; when A is S-MBA, the coordination polyhedron layer bonded to it by electrostatic attraction may also have S-chirality. As a result, the MBA₂PbI₄ layer may have a helical structure that rotates left or right within the crystal, thereby having R- or S-chirality.

An MBA₂PbI₄ layer having R- or S-chirality, i.e., an R- or S-MBA₂PbI₄ layer, may exhibit chirality-induced spin selectivity (CISS) due to the interaction between the helical structure and the spin-orbit coupling (SOC) of holes or electrons, thereby selectively conducting either up or down spins. In one example, when the R-MBA₂PbI₄ layer selectively conducts up spins by providing lower resistance to up spins than down spins, a hole transport layer 30 having S-chirality can selectively conduct down spins by providing lower resistance to down spins than up spins. In another example, if the R-MBA₂PbI₄ layer provides lower resistance to down spins than to up spins, thereby selectively conducting down spins, the hole transport layer 30 having S-chirality can selectively conduct up spins by providing lower resistance to up spins than to down spins.

### Manufacturing Example 4: Organic Light-Emitting Diode Fabrication

An ITO substrate which is a glass substrate coated with an ITO anode was prepared. A mixed solution of PEDOT:PSS (AI4083, Heraeus), which is a conductive material, and PFI (PerFluorinated Ionomer which is perfluorosulfonic acid (PFSA) polymer dispersion) (D520, Dupont), was spin-coated onto the ITO anode. The solution was heat-treated at 150° C. for 30 minutes to form an approximately 40 nm-thick m-PEDOT:PSS hole-injection layer. A solution of R-MBA₂PbI₄ (MBA: methylbenzylammonium) single crystals dissolved in dimethylformamide was then spin-coated onto the hole-injection layer to form a spin-polarizing hole-transport layer. A light-emitting layer was formed by spin-coating a fluorescent material, Super Yellow polymer (Poly(p-phenylene vinylene (PPV) polymer, Livilux® PDY-132, Merck), dissolved in toluene, onto the spin-polarizing hole-transport layer. An electron transport layer was formed by depositing 1,3,5-TPBI (Tris(1-phenyl-1H-benzimidazol-2-yl)benzene) to a thickness of 40 nm under high vacuum conditions (2×10⁻⁷ Torr or less) using a thermal evaporator on the light-emitting layer. A 1 nm thick LiF layer was then deposited thereon to form an electron injection layer. Subsequently, a 100 nm thick aluminum layer, a 100 nm thick nickel ferromagnetic layer, and a 100 nm thick aluminum layer were sequentially deposited to form a cathode, fabricating an organic light-emitting diode (OLED).

### Comparative Example: Fabrication of an Organic Light-Emitting Diode

An organic light-emitting diode was fabricated using the same method as Manufacturing Example 4, except that a 100 nm thick layer of aluminum was deposited on the LiF electron injection layer to form a cathode without a Ni ferromagnetic layer.

### <External Quantum Efficiency and Current Efficiency Measurements>

The external quantum efficiency (EQE) and current efficiency were measured using a Konica Minolta CS-2000 spectroradiometer. Luminance was measured at a 0° viewing angle perpendicular to the device front, and electrical characteristics were simultaneously measured using a Keithley 2450 Source Meter. All measurement data were calculated based on the average values obtained from repeated measurements. Current efficiency was calculated as the amount of light emitted per unit current (cd/A), and the external quantum efficiency was calculated based on the measured luminance, emission spectrum, applied current, and number of carriers. Additionally, the total number of emitted photons was estimated by considering the measured light intensity and radiation angle, thereby deriving a more precise EQE value.

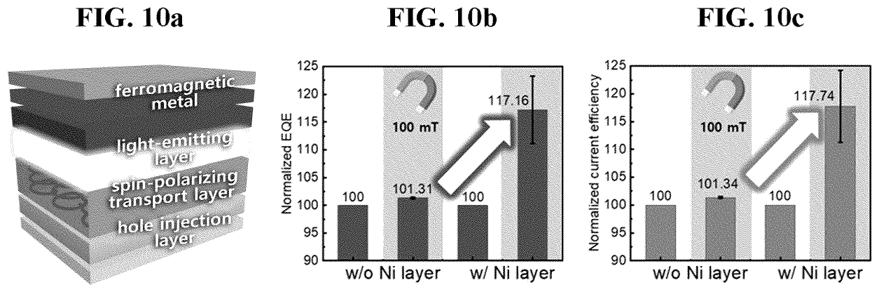

FIGS. 10a, 10b, and 10c shows, respectively, a schematic diagram illustrating the layered structure of the organic light-emitting diode (OLED) according to Manufacturing Example 4, a graph showing Normalized External Quantum Efficiency of the OLEDs according to Manufacturing Example 4 and Comparative Example, and a graph showing Normalized Current Efficiency of the OLEDs according to Manufacturing Example 4 and Comparative Example. The external magnetic field was applied by positioning a magnet with a strength of 100 mT measured by a Gaussmeter above the cathode, and the magnetic field was applied in a direction such that the Ni ferromagnetic layer was spin-down magnetized.

Referring to FIGS. 10b and 10c, it can be seen that the organic light-emitting diode according to Comparative Example does not include a Ni ferromagnetic layer in the cathode layer, and therefore the external quantum efficiency and current efficiency are not significantly affected by the presence or absence of a magnetic field. However, since the organic light-emitting diode according to Manufacturing Example 4 includes a Ni ferromagnetic layer in the cathode layer, the external quantum efficiency and current efficiency were improved to 117.16% and 117.74%, respectively, when a magnetic field was applied compared to when no magnetic field was applied. This means that the luminescence efficiency was improved by including the Ni ferromagnetic layer in the cathode layer together with the spin-polarizing hole transport layer including R-MBA₂PbI₄.

Specifically, the Ni ferromagnetic layer included in the cathode may be magnetized in the down direction by the applied magnetic field, and selectively conduct electrons of the down spin by providing lower resistance to the down spin than to the up spin, and the R-MBA₂PbI₄ included in the spin-polarizing hole transport layer selectively conducts holes of the up spin by providing lower resistance to the up spin than to the down spin, so it can be understood that the holes of the up spin and the electrons of the down spin theoretically generate 100% singlet excitons within the light-emitting layer.

The scope of the present invention is indicated by the claims described below rather than the detailed description above, and all changes or modifications derived from the meaning and scope of the claims and their equivalent concepts should be interpreted as being included in the scope of the present application.

What is claimed is:

1. An organic light-emitting diode comprising:
an anode;
a cathode including a ferromagnetic metal layer that selectively conducts spin-polarized electrons;
a light-emitting layer disposed between the anode and the cathode;
an electron conduction layer disposed between the cathode and the light-emitting layer; and
a spin-polarizing hole transport layer disposed between the anode and the light-emitting layer,
wherein the spin-polarizing hole transport layer supplies spin-polarized holes to the light-emitting layer, and the spin-polarized electrons and the spin-polarized holes recombine within the light-emitting layer.

2. The organic light-emitting diode of claim 1, wherein the spin-polarized electrons and the spin-polarized holes have spin states in opposite directions.

3. The organic light-emitting diode of claim 2, wherein the ratio of singlet excitons among excitons generated by combination of the spin-polarized electrons and the spin-polarized holes within the light-emitting layer is greater than 25% and less than or equal to 100%.

4. The organic light-emitting diode of claim 2, wherein the light-emitting layer is a fluorescent light-emitting layer.

5. The organic light-emitting diode of claim 1, wherein the light-emitting layer includes a host and a dopant, and the spin-polarized electrons and the spin-polarized holes are injected directly into the dopant without passing through the host and recombine in the dopant.

6. The organic light-emitting diode of claim 5, wherein a HOMO (Highest Occupied Molecular Orbital) energy level of the host is lower than a HOMO energy level of the dopant, and a LUMO (Lowest Unoccupied Molecular Orbital) energy level of the host is higher than a LUMO energy level of the dopant.

7. The organic light-emitting diode of claim 5, wherein a difference between a HOMO energy level of the hole transport layer and a HOMO energy level of the host creates an energy barrier for the spin-polarized holes.

8. The organic light-emitting diode of claim 5, wherein a difference between a LUMO energy level of the electron conduction layer and a LUMO energy level of the host creates an energy barrier for the spin-polarized electrons.

9. The organic light-emitting diode of claim 5, wherein the host is a mixed host of an electron donor and an electron acceptor.

10. The organic light-emitting diode of claim 9, wherein a HOMO energy level of the electron donor and a HOMO energy level of the electron acceptor are lower than a HOMO energy level of the dopant, and a LUMO energy level of the electron donor and a LUMO energy level of the electron acceptor are higher than a LUMO energy level of the dopant.

11. The organic light-emitting diode of claim 9, wherein a difference between a HOMO energy level of the hole transport layer and a HOMO energy level of the electron donor creates an energy barrier for the spin-polarized holes.

12. The organic light-emitting diode of claim 9, wherein a difference between a LUMO energy level of the electron conduction layer and a LUMO energy level of the electron acceptor creates an energy barrier for the spin-polarized electrons.

13. The organic light-emitting diode of claim 1, wherein the spin-polarizing hole transport layer is a layer having a chiral asymmetric structure exhibiting either R-chiral or S-chiral chirality.

14. The organic light-emitting diode of claim 13, wherein the spin-polarizing hole transport layer is a chiral metal oxide layer, a chiral perovskite layer, or a chiral organic semiconductor layer.

15. The organic light-emitting diode of claim 14, wherein the chiral perovskite layer includes a perovskite having a chemical formula of ABX₃, A′₂Aₙ₋₁BX₃ₙ₊₁, ABX₄, A₂BX₄, A₂BX₅, A₃BX₅, A₄B₂X₁₀, ABX₅, A₃B₂X₉, AB₂X₁₀ or A₂B₁B′X₆,
wherein the A is an R- or S-chiral organic cation, the A′ is a chiral organic cation having a same chirality as the Abut having a different composition,
the B and the B′ are, independently of each other, metal ions, achiral organic cations, inorganic cations, achiral ammonium ions, or combinations thereof,
the X is F—, Cl—, Br—, I—, or combinations thereof, and
the n is an integer from 1 to 10.

16. The organic light-emitting diode of claim 14, wherein the chiral perovskite layer is a two-dimensional layered perovskite layer.

17. The organic light-emitting diode of claim 16, wherein the chiral perovskite layer is a perovskite layer having the chemical formula A₂BX₄.

18. The organic light-emitting diode of claim 1, wherein the ferromagnetic metal layer is Fe, Ni, Co, FeCo, NiFe, or a composite film thereof.

19. The organic light-emitting diode of claim 1, wherein the cathode further includes a cathode conductive film, which is a conductive film having a lower work function than the anode.

20. The organic light-emitting diode of claim 1, wherein the electron conduction layer includes an electron transport layer adjacent to the light-emitting layer and an electron injection layer adjacent to the cathode.
